(19) United States
(12) Patent Application Publication
(10) Pub. No.: US 2022/0301832 A1
(43) Pub. Date: Sep. 22, 2022

(54) PLASMA PROCESSING APPARATUS

(71) Applicant: Tokyo Electron Limited, Tokyo (JP)

(72) Inventors: Takashi Aramaki, Kurokawa-gun (JP); Hiroshi Tsujimoto, Kurokawa-gun (JP); Lifu Li, Kurokawa-gun (JP); Yusei Kuwabara, Kurokawa-gun (JP); Ryoya Abe, Kurokawa-gun (JP)

(21) Appl. No.: 17/655,071

(22) Filed: Mar. 16, 2022

(30) Foreign Application Priority Data
Mar. 17, 2021 (JP) 2021-043841

(51) Int. Cl. H01J 37/32

(52) U.S. Cl. CPC H01J 37/32642; H01J 37/32715; H01J 37/32495; H01J 2237/327

(57) ABSTRACT

A plasma processing apparatus includes a plasma processing chamber; a plasma generator configured to generate a plasma in the plasma processing chamber; a substrate support disposed in the plasma processing chamber; a first conductive ring disposed to surround a substrate on the substrate support; an insulating ring disposed to surround the first conductive ring; and a second conductive ring disposed to surround the insulating ring, and connected to a ground potential.

### CROSS-REFERENCE TO RELATED APPLICATION

This application claims the benefit of Japanese Patent Application No. 2021-043841 filed on Mar. 17, 2021, the entire disclosure of which is incorporated herein by reference.

### TECHNICAL FIELD

The various aspects and embodiments described herein pertain generally to a plasma processing apparatus.

### BACKGROUND

In plasma etching, an edge ring and a cover ring surrounding a substrate are worn out, and changes in these parts over time affect a process result near an edge of the substrate. For example, Patent Document 1 discloses a plasma processing apparatus having a placing table, an inner edge ring, an outer edge ring, a lift pin, and a moving mechanism. In this plasma processing apparatus, as the edge rings are worn out, the lift pin is raised by the moving mechanism to thereby lift up the inner edge ring. Thus, a top surface of the inner edge ring is controlled to be substantially on a level with a top surface of the substrate, so that a decrease in an etching rate near the edge of the substrate is suppressed.

Patent Document 1: Japanese Patent Laid-open Publication No. 2020-053538

### SUMMARY

In one exemplary embodiment, a plasma processing apparatus includes a plasma processing chamber; a plasma generator configured to generate a plasma in the plasma processing chamber; a substrate support disposed in the plasma processing chamber; a first conductive ring disposed to surround a substrate on the substrate support; an insulating ring disposed to surround the first conductive ring; and a second conductive ring disposed to surround the insulating ring, and connected to a ground potential.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating an example of a plasma processing system according to an exemplary embodiment;

FIG. 2 is a schematic cross sectional view illustrating an example of a plasma processing apparatus according to the exemplary embodiment;

FIG. 3A and FIG. 3B are diagrams illustrating an example of a ring assembly according to the exemplary embodiment;

FIG. 4A and FIG. 4B are diagrams for describing presence or absence of a second conductive ring and a direction of a RF current according to the exemplary embodiment;

FIG. 5A to FIG. 5C are diagrams showing an experimental result regarding presence or absence of the second conductive ring and an etching rate according to the exemplary embodiment; and

FIG. 6 is a diagram showing an experimental result regarding presence or absence of the second conductive ring and an etching rate according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings. In the various drawings, same parts will be assigned same reference numerals, and redundant description will be omitted.

[Plasma Processing System]

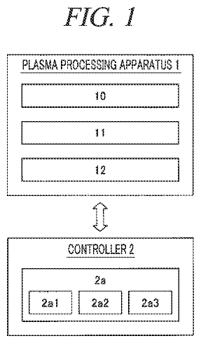

In an exemplary embodiment, a plasma processing system shown in FIG. 1 includes a plasma processing apparatus 1 and a controller 2. The plasma processing apparatus 1 includes a plasma processing chamber 10, a substrate support 11, and a plasma generator 12. The plasma processing chamber 10 has a plasma processing space therein. Further, the plasma processing chamber 10 has at least one gas inlet through which at least one processing gas is supplied into the plasma processing space, and at least one gas outlet through which the gas is exhausted from the plasma processing space. The gas inlet is connected to a gas supply 20 to be described later, and the gas outlet is connected to an exhaust system 40 to be described later. The substrate support 11 is disposed in the plasma processing space, and has a substrate supporting surface on which the substrate is supported.

The plasma generator 12 is configured to generate a plasma from the at least one processing gas supplied into the plasma processing space. The plasma formed in the plasma processing space may be a capacitively coupled plasma (CCP), an inductively coupled plasma (ICP), an electron-cyclotron-resonance (ECR) plasma, a helicon wave plasma (HWP), or a surface wave plasma (SWP). Further, various types of plasma generators including an alternating current (AC) plasma generator and a direct current (DC) plasma generator may be used. In the exemplary embodiment, an AC signal (AC power) used in the AC plasma generator has a frequency in the range of 100 kHz to 10 GHz. Accordingly, the AC signal includes a radio frequency (RF) signal and a microwave signal. In the exemplary embodiment, the RF signal has a frequency ranging from 200 kHz to 150 MHz.

The controller 2 processes computer-executable instructions that cause the plasma processing apparatus 1 to perform various processes described in the present disclosure. The controller 2 may be configured to control the individual components of the plasma processing apparatus 1 to perform various processes described herein. In the exemplary embodiment, a part or the whole of the controller 2 may be included in the plasma processing apparatus 1. The controller 2 may include, for example, a computer 2a. The computer 2a may include, by way of example, a processing unit (central processing unit (CPU)) 2a1, a storage 2a2, and a communication interface 2a3. The processing unit 2a1 may be configured to perform various kinds of control operations based on a program stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

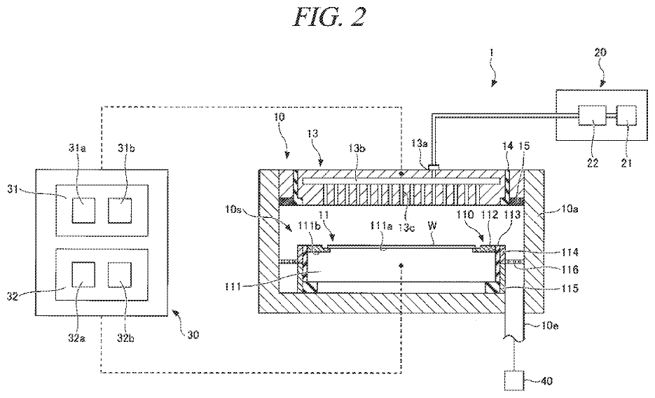

Now, a configuration example of a capacitively coupled plasma processing apparatus as an example of the plasma processing apparatus 1 will be described with reference to FIG. 2. The plasma processing apparatus 1 includes the plasma processing chamber 10, the gas supply 20, a power supply 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a showerhead 13. The substrate support 11 is disposed in the plasma processing chamber 10. The showerhead 13 is disposed above the substrate support 11. In the exemplary embodiment, the showerhead 13 constitutes at least a part of a ceiling of the plasma processing chamber 10. The plasma processing chamber 10 has a plasma processing space 10s defined by the showerhead 13, a sidewall 10a of the plasma processing chamber 10, and the substrate support 11. The sidewall 10a is grounded. The showerhead 13 is surrounded by a ring-shaped insulating member 14. The showerhead 13 and the substrate support 11 are electrically insulated from a housing of the plasma processing chamber 10. In addition, a ring-shaped silicon ground ring 15 is provided at an outer periphery of the insulating member 14. The silicon ground ring 15 has a ground potential, the same as the sidewall 10a.

The substrate support 11 includes a body 111 and a ring assembly 110. The body 111 has a central region (substrate supporting surface) 111a on which a substrate (wafer) W is supported, and an annular region (ring supporting surface) 111b on which the ring assembly 110 is supported. The annular region 111b of the body 111 surrounds the central region 111a of the body 111 when viewed from the top. The substrate W is placed on the central region 111a of the body 111, and the ring assembly 110 is disposed on the annular region 111b of the body 111 to surround the substrate W on the central region 111a of the body 111. In the exemplary embodiment, the body 111 includes a base and an electrostatic chuck. The base includes a conductive member. The conductive member of the base serves as a lower electrode. The electrostatic chuck is placed on top of the base. A top surface of the electrostatic chuck has the substrate supporting surface 111a. Further, although not shown, the substrate support 11 may include a temperature control module configured to regulate at least one of the electrostatic chuck, the ring assembly 110 and the substrate W to a target temperature. The temperature control module may include a heater, a heat transfer medium, a flow path, or a combination thereof. In the flow path, a heat transfer fluid such as brine or a gas flows. Moreover, the substrate support 11 may also include a heat transfer gas supply configured to supply a heat transfer gas into a gap between a rear surface of the substrate W and the substrate supporting surface 111a.

The showerhead 13 is configured to introduce at least one processing gas from the gas supply 20 into the plasma processing space 10s. The showerhead 13 has at least one gas inlet 13a, at least one gas diffusion space 13b, and a plurality of gas introduction openings 13c. The processing gas supplied into the gas inlet 13a passes through the gas diffusion space 13b and is introduced into the plasma processing space 10s through the plurality of gas introduction openings 13c. Further, the showerhead 13 includes a conductive member. The conductive member of the showerhead 13 functions as an upper electrode. Furthermore, the gas introduction unit may include, in addition to the showerhead 13, one or more side gas injectors (SGI) provided in one or more openings formed in the sidewall 10a.

The gas supply 20 may include one or more gas sources 21 and one or more flow rate controllers 22. In the exemplary embodiment, the gas supply 20 is configured to supply the at least one processing gas from the corresponding gas sources 21 to the showerhead 13 via the corresponding flow rate controllers 22. Each flow rate controller 22 may include, by way of example, a mass flow controller or a pressure control type flow rate controller. Further, the gas supply 20 may include at least one flow rate modulating device configured to modulate or pulse the flow rate of at least one processing gas.

The power supply 30 includes a RF power supply 31 connected to the plasma processing chamber 10 via at least one impedance matching circuit. The RF power supply 31 is configured to supply at least one RF signal (RF power), such as a source RF signal and a bias RF signal, to the conductive member of the substrate support 11 and/or the conductive member of the showerhead 13. Accordingly, the plasma is formed from the at least one processing gas supplied into the plasma processing space 10s. Thus, the RF power supply 31 may function as at least a part of the plasma generator 12. Further, by supplying the bias RF signal to the conductive member of the substrate support 11, a bias potential is generated in the substrate W, and ion components in the formed plasma can be attracted into the substrate W.

In the exemplary embodiment, the RF power supply 31 includes a first RF generator 31a and a second RF generator 31b. The first RF generator 31a is coupled to the conductive member of the substrate support 11 and/or the conductive member of the showerhead 13 via at least one impedance matching circuit, and is configured to generate the source RF signal (source RF power) for plasma formation. In the exemplary embodiment, the source RF signal has a frequency ranging from 13 MHz to 150 MHz. In the exemplary embodiment, the first RF generator 31a may be configured to generate a plurality of source RF signals having different frequencies. The generated one or more source RF signals are supplied to the conductive member of the substrate support 11 and/or the conductive member of the showerhead 13. The second RF generator 31b is coupled to the conductive member of the substrate support 11 via at least one impedance matching circuit, and is configured to generate the bias RF signal (bias RF power). In the exemplary embodiment, the bias RF signal has a frequency lower than the frequency of the source RF signal. In the exemplary embodiment, the bias RF signal has a frequency in the range of 400 kHz to 13.56 MHz. In the exemplary embodiment, the second RF generator 31b may be configured to generate a plurality of bias RF signals having different frequencies. One or more of the generated bias RF signals are supplied to the conductive member of the substrate support 11. Further, in various exemplary embodiments, at least one of the source RF signal and the bias RF signal may be pulsed.

Furthermore, the power supply 30 may include a DC power supply 32 coupled to the plasma processing chamber 10. The DC power supply 32 includes a first DC generator 32a and a second DC generator 32b. In the exemplary embodiment, the first DC generator 32a is connected to the conductive member of the substrate support 11, and is configured to generate a first DC signal. The generated first DC signal is applied to the conductive member of the substrate support 11. In the exemplary embodiment, the first DC signal may be applied to another electrode, such as an electrode within the electrostatic chuck. In the exemplary embodiment, the second DC generator 32b is connected to the conductive member of the showerhead 13, and is configured to generate a second DC signal. The generated second DC signal is applied to the conductive member of the showerhead 13. In various exemplary embodiments, the first and second DC signals may be pulsed. In addition, the first and second DC generators 32a and 32b may be provided in addition to the RF power supply 31, or the first DC generator 32a may be provided instead of the second RF generator 31b.

The exhaust system 40 may be connected to a gas outlet 10e provided at a bottom of the plasma processing chamber 10, for example. The exhaust system 40 may include a pressure control valve and a vacuum pump. An internal pressure of the plasma processing space 10s is adjusted by the pressure control valve. The vacuum pump may include a turbo molecular pump, a dry pump, or a combination thereof.

[Ring Assembly]

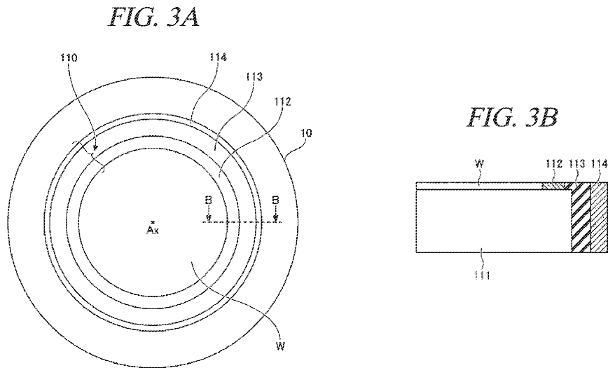

FIG. 3A and FIG. 3B illustrate a configuration example of the ring assembly 110 according to the exemplary embodiment. FIG. 3A is a top view of the substrate support 11, and FIG. 3B is a cross sectional view taken along a line B-B of FIG. 3A. As shown in FIG. 2 to FIG. 3B, the ring assembly 110 includes one or more annular members. The one or more annular members include a first conductive ring 112, a cover ring 113, and a second conductive ring 114. The first conductive ring 112 is a ring-shaped member having conductivity, and may be formed of any one of various kinds of materials such as silicon (Si), silicon carbide (SiC), and silicon oxide. The first conductive ring 112 is disposed on the substrate support 11 to surround the substrate W on the substrate support 11.

The first conductive ring 112, the cover ring 113, and the second conductive ring 114 are coaxially disposed around a central axis Ax of the plasma processing chamber 10.

The cover ring 113 surrounds the first conductive ring 112 and the body 111, and is disposed on outer sidewalls of the first conductive ring 112 and the body 111. The cover ring 113 is a ring-shaped member having insulation property, and may be formed of quartz or alumina. The cover ring 113 is an example of an insulating ring disposed so as to surround the first conductive ring.

The second conductive ring 114 is disposed to surround the cover ring 113 and connected to the ground potential. The second conductive ring 114 is disposed on an outer sidewall of the cover ring 113. The second conductive ring 114 is a ring-shaped member having conductivity, and may be formed of any one of various kinds of materials such as silicon, silicon carbide, and silicon oxide. In the exemplary embodiment, the second conductive ring 114 is disposed such that a top surface of the second conductive ring 114 is substantially on a level with a top surface of the cover ring 113. In the exemplary embodiment, the second conductive ring 114 has a vertically elongated rectangular cross-sectional shape. In addition, the second conductive ring 114 may be disposed such that the top surface of the second conductive ring 114 is lower than the top surface of the cover ring 113.

Further, the second conductive ring 114 may be disposed such that the top surface of the second conductive ring 114 is higher than the top surface of the cover ring 113. In one exemplary embodiment, the second conductive ring 114 may have a protruding portion that covers a part of the top surface of the cover ring 113. In this case, the second conductive ring 114 has an L-shaped cross-sectional shape with an upper portion thereof protruding inwards. That is, the L-shaped cross-sectional shape has a vertically elongated rectangular portion and a protruding portion protruding inwards from an upper portion of the vertically elongated rectangular portion. By configuring the top surface of the second conductive ring 114 to be higher than the top surface of the cover ring 113, the plasma may be physically confined in the plasma processing space 10s more easily.

The one or more annular members of the ring assembly 110 may include a third conductive ring 115. The third conductive ring 115 is a ring-shaped member having conductivity, and may be formed of a conductive member such as aluminum (Al). The third conductive ring 115 is disposed under the second conductive ring 114 and connected to the ground potential. That is, the second conductive ring 114 is connected to the ground potential via the third conductive ring 115.

A conductive baffle plate 116 connected to the ground potential may be disposed around the substrate support 11. In this case, the second conductive ring 114 may be connected to the ground potential via the conductive baffle plate 116. The conductive baffle plate 116 may be formed of a conductive member such as aluminum. The conductive baffle plate 116 is provided with a plurality of through holes, and is configured to exhaust the gas within the plasma processing space 10s from the gas outlet 10e through the plurality of through holes.

[Wear-Out of Parts of Ring Assembly]

If a plasma processing such as etching is performed in the plasma processing space 10s, parts (the first conductive ring 112, the cover ring 113, etc.) of the ring assembly 110 are worn out. When the second conductive ring 114 is not provided, a change in an etching rate or the like occurs near the edge of the substrate W with a lapse of time due to the wear-out of the parts, having an influence on the process. As one of the reasons for this, it is deemed to be because electrostatic capacity of the parts decreases due to the wear-out of the parts, and the direction of the RF signal supplied from the RF power source 31 changes.

Recently, a process of applying a high-power RF signal to the substrate support 11 or the showerhead 13, such as a plasma etching process with a high aspect ratio, is increasing. For this reason, a sputter rate of the sidewall 10a, the conductive baffle plate 116 or the like increases during the plasma processing, causing the parts to be worn out faster. Therefore, it becomes important to reduce plasma density in a region other than the plasma processing space 10s above the substrate W to thereby suppress the wear-out of the parts such as the sidewall 10a. In view of the foregoing, in the plasma processing apparatus 1 of the present disclosure, the second conductive ring 114 is provided on an outer side surface of the cover ring 113 of the ring assembly 110 surrounding the substrate W, and the second conductive ring 114 is connected to ground potential via the third conductive ring 115.

With this configuration, by allowing the second conductive ring 114 to function as a grounding member, (1) it is possible to take measures for reducing the influence on the process, such as a decrease in the etching rate or the like, for the changes over time caused by the wear-out of the first conductive ring 112 and the cover ring 113. Further, it is possible to (2) suppress the sputter rate of the entire plasma processing chamber 10, and (3) confine the plasma into the plasma processing space 10s by a magnetic field. Hereinafter, (1) to (3) will be elaborated in order.

[(1) Measures for Changes Over Time]

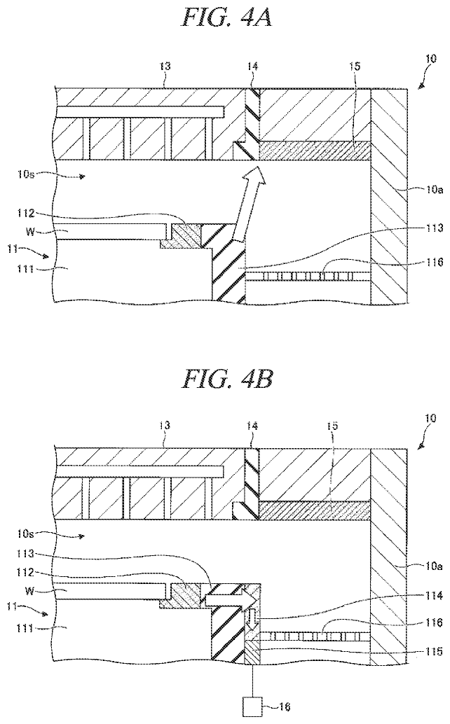

First, (1) the measures for the changes over time due to the wear-out of the parts will be explained with reference to FIG. 4A and FIG. 4B. FIG. 4A shows the direction of the RF signal supplied from the RF power supply 31 when the ring assembly 110 does not include the second conductive ring 114, whereas FIG. 4B shows the direction of the RF signal when the second conductive ring 114 is provided.

In the absence of the second conductive ring 114 shown in FIG. 4A, the RF current applied from the RF power supply 31 flows through surface layers of the body 111, the first conductive ring 112 and the cover ring 113, and then flows toward the silicon ground ring 15 of the ground potential on the opposite side in a substantially vertical direction. That is, the direction of the RF current is formed to be substantially perpendicular to the cover ring 113. In this case, the top surface of the cover ring 113 is worn in a substantially horizontal direction, and when an impedance in the direction of the RF current is changed according to a change in a capacitance of the cover ring 113, the direction of the RF current, which is approximately perpendicular to the wear-out direction of the cover ring 113, may be easily affected. As a result, the etching rate at the edge region of the substrate W tends to fluctuate.

In contrast, in the presence of the second conductive ring 114 as shown in FIG. 4B, the RF current flows through the surface layers of the body 111, the first conductive ring 112 and the cover ring 113, and then flows from the third conductive ring 115 to the ground via the second conductive ring 114. That is, the direction of the RF current is formed to be substantially horizontal with respect to the cover ring 113. In this case, since a surface of the cover ring 113 which changes with the lapse of time due to the wear-out thereof is approximately horizontal and is in the same direction as the direction of the RF current, the wear-out of the cover ring 113 may not affect the direction of the RF current. As a result, it becomes difficult for the etching rate to fluctuate at the edge region of the substrate W, so that the influence on the process due to the wear-out of the cover ring 113 can be reduced.

Although the above description has been provided for the wear-out of the cover ring 113 and the direction of the RF current, the same goes for the wear-out of the first conductive ring 112. That is, by disposing the second conductive ring 114 of the present disclosure, resistance to the wear-out of the first conductive ring 112 and/or the cover ring 113 is obtained, so that the reduction in the etching rate at the edge of the substrate W can be suppressed.

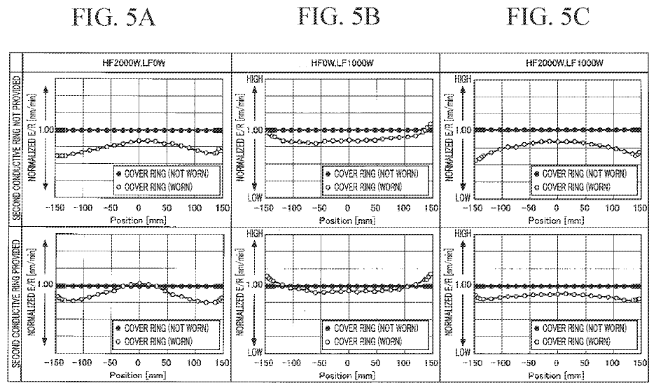

FIG. 5A to FIG. 5C are diagrams showing an experimental result regarding presence or absence of the second conductive ring 114 and an etching rate according to the exemplary embodiment. In this experiment, a substrate W is prepared in each of a plasma processing apparatus which does not have the second conductive ring 114 and the plasma processing apparatus 1 (see FIG. 1) of the present disclosure which is equipped with the second conductive ring 114, and a silicon oxide film (SiO₂) on each substrate W is etched. In this experiment, for the presence or absence of the second conductive ring 114 and a variation in the etching rate, an etching rate when the cover ring 113 is new and an etching rate when the cover ring 113 is worn out are compared.

In FIG. 5A to FIG. 5C, among RF signals, the source RF signal is denoted as ‘HF,’ and the bias RF signal is denoted as ‘LF.’ In FIG. 5A, etching is performed under the condition that HF is 2000 W and LF is 0 W. In FIG. 5B, etching is performed under the condition that HF is 0 W and LF is 1000 W. In FIG. 5C, etching is performed under the condition that HF is 2000 W and LF is 1000 W. In FIG. 5A to FIG. 5C, HF and LF are applied to the body 111.

A horizontal axis of each graph indicates a position of the substrate W in a diametrical direction with a center of the substrate W having a diameter of 300 mm being set as 0 mm. A vertical axis represents an average value of normalized etching rates at each position in the diametrical direction of the substrate Won the horizontal axis. Black circles (•) on the graph indicate the etching rates when the cover ring 113 is not worn (when it is new), which are normalized as being 1. White circles (◯) on the graph indicate the etching rates when the cover ring 113 is worn out, and these etching rates are expressed as ratios to the normalized etching rates (•) when the cover ring 113 is new.

When the second conductive ring 114 is not provided, the decrease in the etching rate is observed, as shown in FIG. 5A to FIG. 5C, as compared to the case where the second conductive ring 114 is provided.

As can be seen from the above result, in any case of FIG. 5A to FIG. 5C, when the second conductive ring 114 is present, the decrease in the etching rate due to the wear-out of the cover ring 113 can be suppressed, as compared to the case where the second conductive ring 114 is not provided. In particular, the decrease in the etching rate near the edge of the substrate W can be suppressed, which implies that providing the second conductive ring 114 can be an effective countermeasure against the change of the cover ring 113 over time.

[(2) Suppression of Sputter Rate]

Now, (2) suppression of the sputter rate of the entire plasma processing chamber 10 will be described. When the second conductive ring 114 is not provided, there is no ground potential near the cover ring 113. For this reason, the RF current flows through the surface layers of the body 111, the first conductive ring 112 and the cover ring 113, and then flows through the silicon ground ring 15 and/or the sidewall 10a of the ground potential from the side surface of the cover ring 113. Accordingly, the direction of the RF current is formed on the side surface of the cover ring 113, so that plasma density increases in a space outer than the cover ring 113, and the plasma is formed. As a result, sputtering of the conductive baffle plate 116 and the sidewall 10a of the plasma processing chamber 10 is accelerated.

In contrast, in the presence of the second conductive ring 114, there exists the ground potential near the cover ring 113. That is, the second conductive ring 114 is connected to the third conductive ring 115 of the ground potential and is set to have the ground potential. For this reason, after flowing through the surface layers of body 111, the first conductive ring 112 and the cover ring 113, the RF current flows through the third conductive ring 115 via the second conductive ring 114. That is, the second conductive ring 114 serves as a shielding plate for the RF current, so that the direction of the RF current is not formed on the side surface of the second conductive ring 114. Accordingly, the plasma density is reduced in a space outer than the second conductive ring 114, and the plasma is not formed on the sidewall 10a side. As a result, the sputtering of the sidewall 10a and the conductive baffle plate 116 is suppressed, and the wear-out of the sidewall 10a and the conductive baffle plate 116 is reduced. Therefore, the sputter rate at the outer side than the substrate W can be suppressed.

As described above, since the second conductive ring 114 functions as the shielding plate for the RF current, the efficiency of the RF power contributing to the plasma formation in the space above the substrate W can be enhanced. As a result, the plasma density in the plasma processing space 10s above the substrate W can be increased, whereas the plasma density in the other spaces can be reduced. As stated above, by providing the second conductive ring 114, the sputter rate of the entire plasma processing chamber 10 can be suppressed, and the density of the plasma formed in the plasma processing space 10s can be increased to be higher than the density of the plasma formed when the second conductive ring 114 is not provided.

[(3) Confinement of Plasma by Magnetic Field]

Now, (3) confinement of plasma into the plasma processing space 10s by the magnetic field will be discussed. The second conductive ring 114 is connected to the ground potential via the third conductive ring 115. For this reason, the RF current applied from the RF power supply 31 flows through the second conductive ring 114 from top to bottom. A DC current applied from the DC power supply 32 also flows through the second conductive ring 114 from top to bottom, and then flows to the ground via the third conductive ring 115.

At this time, when the current flows from top to bottom, the magnetic field is generated in a direction orthogonal to the direction of the current. The generated magnetic field is proportional to the amount of the current, so it increases as the amount of the current increases. The generated magnetic field acts to confine the plasma in the plasma processing space 10s above the substrate W.

If the magnetic field is generated, charged particles are confined in the plasma processing space 10s by a force acting on them, that is, a Lorentz force.

In this way, as a current flowing through the second conductive ring 114 from the top to the bottom thereof forms the magnetic field, the plasma can be confined in the plasma processing space 10s.

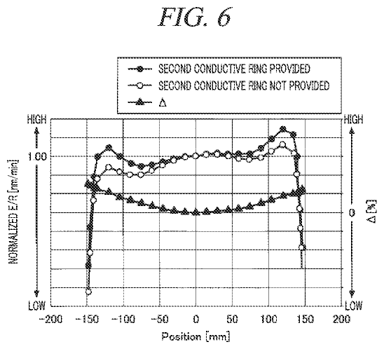

FIG. 6 is a diagram showing an experimental result regarding presence or absence of the second conductive ring 114 and an etching rate according to the exemplary embodiment. In this experiment, a substrate W is prepared in each of a plasma processing apparatus which does not have the second conductive ring 114 and the plasma processing apparatus 1 (see FIG. 1) of the present disclosure which is equipped with the second conductive ring 114. A silicon oxide film (SiO₂) on each substrate W is etched. In this experiment, the presence or absence of the second conductive ring 114 and a change in the etching rate are compared.

A horizontal axis of the graph indicates a position of the substrate W in a diametrical direction with a center of the substrate W having a diameter of 300 mm being set as 0 mm. A vertical axis (left) represents an average value of normalized etching rates at each position in the diametrical direction of the substrate W on the horizontal axis. White circles (◯) on the graph indicate etching rates when the second conductive ring 114 is not provided, which are normalized with an etching rate at the center (0 mm) of the substrate W being 1. Black circles (•) on the graph indicate etching rates when the second conductive ring 114 is provided, and these etching rates are expressed as ratios to the normalized etching rates (◯) when the second conductive ring 114 is not provided. A vertical axis (right) represents a difference (%) calculated by subtracting the etching rate in the absence of the second conductive ring 114 from the etching rate in the presence of the second conductive ring 114, which are indicated by black triangles (▴) on the graph.

As can be seen from the result of this experiment, when the second conductive ring 114 is present, the etching rate becomes higher, as compared to the case where the second conductive ring 114 is not provided. This indicates that the second conductive ring 114 functions as the shielding plate to confine the plasma in the plasma processing space 10s, thus increasing the plasma density in the plasma processing space 10s and, resultantly, increasing the etching rate.

In particular, in the relationship between the presence or absence of the second conductive ring 114 and the difference (%) in the etching rate, which is indicated by the black triangles (▴), the difference in the etching rate between the case where the second conductive ring 114 is present and the case where the second conductive ring 114 is not present is found to increase when it goes from the center (0 mm) of the substrate W to the edge thereof.

That is, when the second conductive ring 114 is present, the plasma is confined in the plasma processing space 10s, as compared to the case where the second conductive ring 114 is not present. In particular, when the second conductive ring 114 is present, the etching rate at the edge side of the substrate W is significantly increased, and the second conductive ring 114 functions as the shielding plate to enhance the effect of confining the plasma.

[Actuator]

Finally, a case where the second conductive ring 114 is configured to be vertically movable will be described.

The second conductive ring 114 is connected to an actuator (lift mechanism) 16 via the third conductive ring 115. The actuator 16 is configured to move the second conductive ring 114 and the third conductive ring 115 up and down (in a vertical direction). In the state that the second conductive ring 114 is lowered, the top surface of the second conductive ring 114 is substantially on a level with the top surface of the cover ring 113. Some of the charged particles in the plasma move outwards from the plasma processing space 10s. If the plasma density increases near the outer periphery of the substrate support 11, that is, near the sidewall 10a due to the charged particles which are moving outwards, the sputtering of the sidewall 10a or the like is accelerated as stated above.

In view of the foregoing, the second conductive ring 114 is configured to be movable up and down by the actuator 16 via the third conductive ring 115. The second conductive ring 114 is raised or lowered during the process. Accordingly, the direction of the RF current directed to the outside of the substrate support 11 is shielded, and the charged particles which are moving outwards is confined in the plasma processing space 10s. In this way, the plasma can be confined in the plasma processing space 10s.

The raising and lowering of the second conductive ring 114 by the actuator 16 may be performed while the substrate processing such as etching is being performed in the plasma processing apparatus 1, or may be performed before or after that. For example, the raising and lowering of the second conductive ring 114 by the actuator 16 may be controlled according to the plasma to be formed and the processing to be performed. Accordingly, even during the process, the density of plasma can be changed instantaneously, and formation of plasma having a density required for the substrate processing can be achieved.

When the second conductive ring 114 is raised to the uppermost position, if the third conductive ring 115 of aluminum is exposed above the conductive baffle plate 116, the process performed in the plasma processing space 10s may be affected. Thus, the length of the second conductive ring 114 in the vertical direction is designed such that the aluminum of the third conductive ring 115 is not exposed above the conductive baffle plate 116 when the second conductive ring 114 is raised to the uppermost position. Further, it is desirable that a plasma-resistant coating is formed on at least an upper portion of the second conductive ring 114. In the present disclosure, a plasma-resistant coating made of an yttria (Y)-containing material is formed on a surface of the second conductive ring 114.

The second conductive ring 114 may be configured as one body with the third conductive ring 115. In this case, the integrated body is referred to as an integration ring 114. The actuator 16 is connected to the integration ring 114, and moves the integration ring 114 up and down (in a vertical direction). The integration ring 114 is an example of the second conductive ring.

In one exemplary embodiment, the second conductive ring 114 includes a conductor having an upper portion and a lower portion, and a plasma-resistant coating formed on the upper portion of the conductor. The lower portion of the conductor is connected to the ground potential.

As described above, according to the plasma processing apparatus 1 of the present exemplary embodiment, by providing the second conductive ring 114, influence of the change in the ring assembly 110 around the substrate W over time can be reduced. That is, by disposing the second conductive ring 114 on the sidewall of the cover ring 113, resistance to the changes in the first conductive ring 112 and the cover ring 113 over time can be enhanced.

In addition, the sputter rate at an outer periphery of the substrate W can be suppressed, so that wear-out of the sidewall 10a and the conductive baffle plate 116 may be suppressed. In addition, the confinement of the plasma by the magnetic field may increase RF power efficiency, resulting in an increase of the plasma density in the plasma processing space 10s.

In the future, the RF power will be increased in a high aspect ratio contact (HARC) process or the like, so that the plasma processing chamber 10 itself is more likely to be etched. In such an environment, by providing the second conductive ring 114 according to the present disclosure, the plasma processing apparatus 1 can be configured to have resistance to changes in various parts such as the ring assembly 110 with the lapse of time. Further, as the plasma is confined by the magnetic field through the use of the second conductive ring 114, the plasma density on the substrate W can be increased, so that the efficiency of the substrate processing such as etching can be improved. In addition, since the magnetic field formed by the second conductive ring 114 is proportional to the amount of the current, it is possible to increase the plasma confinement effect as the RF power is increased.

It should be noted that the plasma processing apparatus according to the above-described exemplary embodiments are illustrative in all aspects and are not anyway limiting. The above-described exemplary embodiments can be modified and improved in various ways without departing from the scope and the spirit of claims. Unless contradictory, other configurations may be adopted, and the disclosures in the various exemplary embodiments can be combined appropriately.

The plasma processing apparatus of the present disclosure may be applicable to any of various types of apparatuses such as an atomic layer deposition (ALD) apparatus, a capacitively coupled plasma (CCP) apparatus, an inductively coupled plasma (ICP) apparatus, a radial line slot antenna (RLSA), an electron cyclotron resonance plasma (ECR), a helicon wave plasma (HWP) apparatus. Furthermore, without being limited to the etching process, the plasma processing apparatus may also perform a film forming process, an aching process, etc., as long as the plasma processing apparatus is used to perform a processing on a substrate by using plasma.

In addition, the second conductive ring 114 may be configured as one body with the conductive baffle plate 116. In this case, this integrated second conductive ring 114 is also an example of the second conductive ring. The integrated second conductive ring 114 in this case is a conductor, and may be formed of, for example, aluminum. A plasma-resistant coating is formed on an upper portion of the integrated second conductive ring 114. The plasma-resistant coating may be formed by coating an yttria (Y)-containing material. A lower portion of the integrated second conductive ring 114 is connected to the ground potential.

According to the exemplary embodiment, it is possible to reduce the influence on the process due to the change in the parts around the substrate with the lapse of time.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A plasma processing apparatus, comprising:
a plasma processing chamber;
a plasma generator configured to generate a plasma in the plasma processing chamber;
a substrate support disposed in the plasma processing chamber;
a first conductive ring disposed to surround a substrate on the substrate support;
an insulating ring disposed to surround the first conductive ring; and
a second conductive ring disposed to surround the insulating ring, and connected to a ground potential.

2. The plasma processing apparatus of claim 1,
wherein the second conductive ring is disposed on an outer sidewall of the insulating ring.

3. The plasma processing apparatus of claim 1,
wherein the second conductive ring is disposed such that a top surface of the second conductive ring is the same height as a top surface of the insulating ring.

4. The plasma processing apparatus of claim 1,
wherein the second conductive ring is disposed such that a top surface of the second conductive ring is higher than a top surface of the insulating ring.

5. The plasma processing apparatus of claim 1,
wherein the insulating ring is made of quartz or alumina.

6. The plasma processing apparatus of claim 1,
wherein the first conductive ring is made of any one of silicon (Si), silicon carbide (SiC), and silicon oxide.

7. The plasma processing apparatus of claim 1,
wherein the second conductive ring is made of any one of silicon (Si), silicon carbide (SiC), and silicon oxide.

8. The plasma processing apparatus of claim 1,
wherein the second conductive ring has a vertically elongated rectangular cross-sectional shape.

9. The plasma processing apparatus of claim 1,
wherein the second conductive ring has an L-shaped cross-sectional shape with an upper portion thereof protruding inwards.

10. The plasma processing apparatus of claim 1, further comprising:
an actuator configured to vertically move the second conductive ring.

11. The plasma processing apparatus of claim 1, further comprising:
a third conductive ring disposed below the second conductive ring, and connected to the ground potential,
wherein the second conductive ring is connected to the ground potential via the third conductive ring.

12. The plasma processing apparatus of claim 11,
wherein the third conductive ring is made of aluminum (Al).

13. The plasma processing apparatus of claim 11, further comprising:
an actuator configured to vertically move the second conductive ring and the third conductive ring.

14. The plasma processing apparatus of claim 1, further comprising:
a conductive baffle plate disposed around the substrate support, and connected to the ground potential,
wherein the second conductive ring is connected to the ground potential via the conductive baffle plate.

15. The plasma processing apparatus of claim 1,
wherein the second conductive ring comprises a conductor having an upper portion and a lower portion, and a plasma-resistant coating formed on the upper portion of the conductor, and
the lower portion of the conductor is connected to the ground potential.

16. The plasma processing apparatus of claim 15,
wherein the conductor is made of aluminum (Al), and
the plasma-resistant coating contains yttria (Y).
